(19) United States
(12) Patent Application Publication
(10) Pub. No.: US 2006/0145354 A1
(43) Pub. Date: Jul. 6, 2006

(54) Diode

(76) Inventors: Karin Hamsen, Tubingen (DE); Richard Siptz, Reutlingen (DE)

Correspondence Address: KENYON & KENYON LLP, ONE BROADWAY, NEW YORK, NY, 10004, US

(21) Appl. No.: 10/527,310

(22) PCT Filed: Jun. 3, 2003
(86) PCT No.: PCT/DE03/01811

§ 371 Date: Nov. 28, 2005

(30) Foreign Application Priority Data
Sep. 12, 2002 (DE) 102 42 521.3

(51) Int. Cl. H01L 23/48

(52) U.S. Cl. 257/774

(57) ABSTRACT

A diode having a press-fit base includes an axially extending mounting region for a semiconductor chip and a head wire affixed to the semiconductor chip. The head wire has a stepped wire connection or a region which forms a sealed housing together with the press-fit base and a sleeve. The cavities produced in the housing are filled with encapsulating material for stabilizing purposes, encapsulating material being present only inside the housing.

### FIELD ON THE INVENTION

The present invention is directed to a diode.

### BACKGROUND INFORMATION

It is known to configure diodes for medium to higher capacities as press-fit diodes. These press-fit diodes, which are used, for example, as rectifier diodes in the form of a rectifier system for rectifying the current provided by vehicle generators, have a press-fit base, which is pressed into a matching recess of a fastening element. The press-fit base at the same time provides a stable thermal and electrical connection between the diode and the rectifier system. The press-fit base has a mounting section on which a semiconductor chip is affixed by soldering, for instance. A so-called head wire is in turn affixed to the semiconductor chip, for instance by soldering as well, the head wire being fixedly connected to a phase-supply line of the vehicle generator.

Since mechanical vibrations occur during normal operation of a motor vehicle, which also exert stress on the diode and its affixation, it is conventional to encapsulate the diode or diodes so as to establish a keyed connection between the head wire and the press-fit base. Such a keyed connection is utilized to provide traction relief for the sensitive semiconductor chip and the solder layers between the semiconductor chip and the press-fit base on the one hand and the head wire on the other hand. Additional means usually project into the encapsulation and improve the required traction relief.

Another possibility for better traction relief is described in connection with a rectifier diode in German Patent No. DE-OS 43 41 269. In this embodiment of a rectifier diode the semiconductor chip is soldered onto the press-fit base and the head wire is soldered to the semiconductor chip. A collar or sleeve joined to the press-fit base surrounds the semiconductor chip and the head as well as sections of the head wire. The produced free space is filled with cast resin or epoxy, which ensures stability once it hardens. In addition a collar is provided at the base, which guarantees an immovable fixation of semiconductor chip, diode head and head wire after encapsulation with the encapsulating material or the cast resin.

### SUMMARY

A diode according to an example embodiment of the present invention may have the advantage over the conventional design approaches that the quantity of the encapsulating material may be reduced. Both less epoxy and less plastic are needed for the sleeve. The quantity reduction in the required encapsulating material advantageously results not only in cost savings but also in an advantageous minimizing of combustible materials in the diode.

These advantages may be achieved by utilizing a stepped head wire, which is joined to the head by means of a soldering layer, for instance, and forms a housing together with a sleeve joined to the base. The cavity inside the housing, which is delimited by the base, semiconductor chip, head, stepped wire connection and sleeve, is smaller than in the conventional designs. As a result, only a small quantity of encapsulating material is advantageously required to fill the cavity. The measures according to the present invention advantageously do not reduce the stability.

It is also expedient here that, within certain limits, the design of the head may be adapted to the individual requirements, a conical head or a stepped head being possible, for instance.

It is particularly advantageous that there is no fire risk when the diode is overloaded, for instance by polarity reversal of the battery during use in a motor vehicle and as a result of the extremely high temperatures of several hundred degrees that will occur in such a case, due to the step in the head of the wire and is advantageously situated inside a sealed housing.

### BRIEF DESCRIPTION OF THE DRAWINGS

FIG. 1 shows a first example embodiment of the present invention.

FIG. 2 shows a second example embodiment of the present invention.

FIG. 3 shows a more detailed configuration of the example embodiment according to FIG. 2.

FIGS. 4-6 show specific embodiments of press-fit diodes that constitute part of the related art.

### DETAILED DESCRIPTION OF EXAMPLE EMBODIMENTS

FIG. 1 shows a first exemplary embodiment of the present invention. A cross section through a diode, in particular a press-fit diode, is shown. Diode 10 includes a press-fit base 11, which changes into an axially extending mounting region 12. A semiconductor chip 13, such as a silicon chip, is joined to mounting region 12 of press-fit base 11 by a soldering layer 14. Semiconductor chip 13 is connected to head 16 of a head wire 17 by means of an additional soldering layer 15. Head 16 in the exemplary embodiment of FIG. 1 has three regions, 18, 19, 20, having different diameters. Region 21 forms the stepped wire connection. This region 21 at the wire shaft changes over to head 16 or region 20 of head 16.

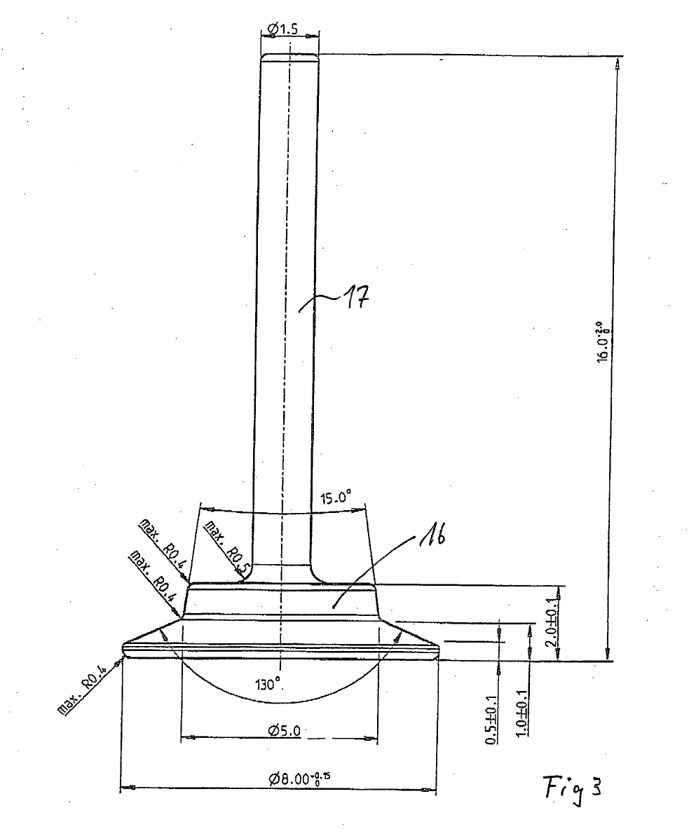

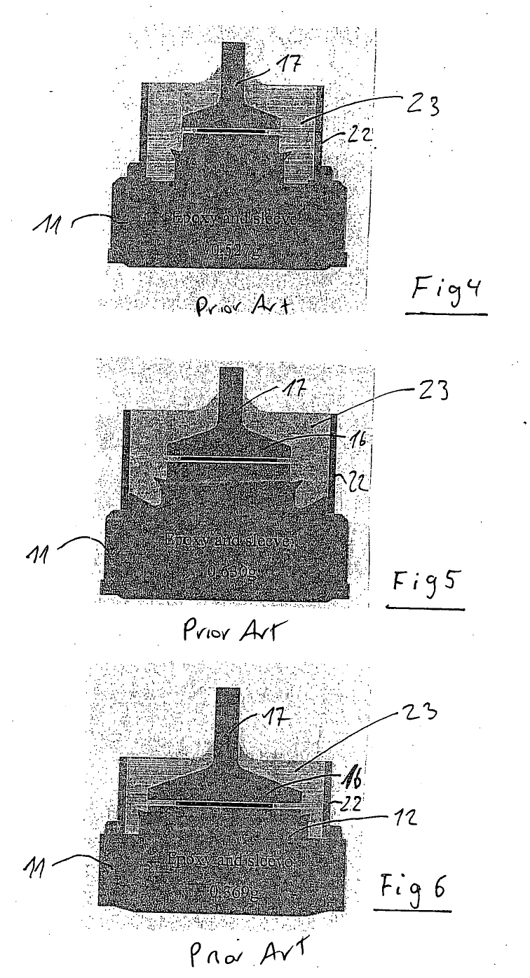

Region 21 of the stepped head wire forms a sealed housing together with press-fit base 11 and a sleeve 22. Sleeve 22 is made of plastic, for example. The cavities inside the housing are filled with encapsulating material 23 such as epoxy or some other plastic, so that t semiconductor chip 13 itself is mechanically fixated and protected from moisture. The design shown in FIG. 1 ensures the seal tightness of the housing. Semiconductor chip 13 is protected from moisture without the encapsulating material covering the entire head 16 as it does in the known approaches represented in FIGS. 4, 5 and 6.

In the exemplary embodiment shown in FIG. 1, head 16 of head wire 17 has three regions, 18, 19, 20, with different diameters; regions 18 and 19 may also be combined into one region.

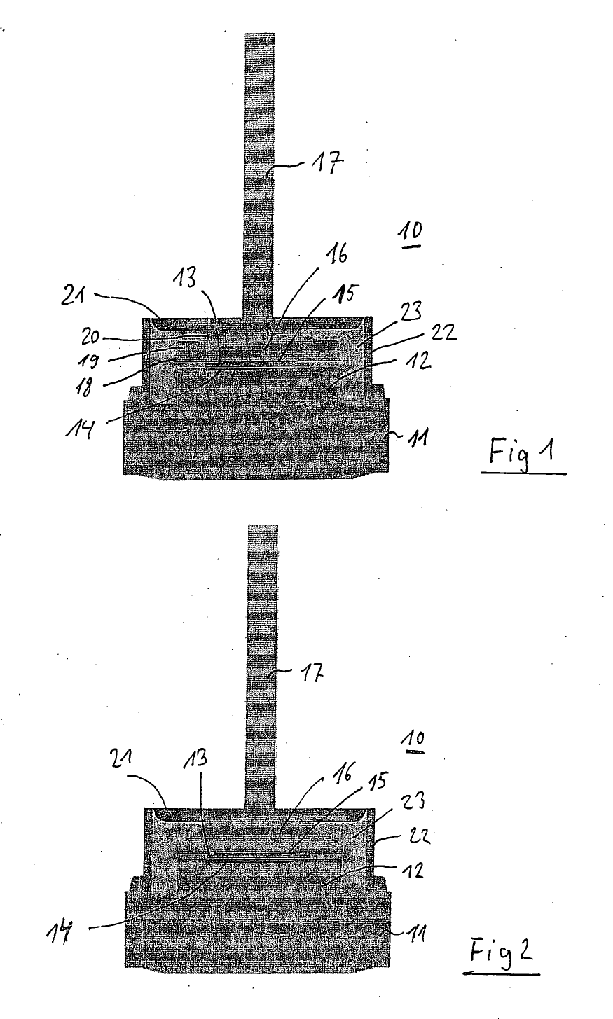

FIG. 2 shows another example embodiment of the present invention, which differs from the example embodiment according to FIG. 1 merely in that head 16 is cone-shaped or bell-shaped. However, in the exemplary embodiment shown in FIG. 2 as well, press-fit base 11 with mounting region 12, sleeve 22 and region 21 of the stepped wire connection form a sealed housing, which is filled with encapsulating material and protects semiconductor chip 13.

A more detailed representation of the head wire and especially advantageous measurements are shown in FIG. 3. Head 16 has several regions having different diameters and bevels. The details may be gathered from the drawing.

FIGS. 4, 5 and 6 show conventional press-fit diodes. It can be seen that these conventional press-fit diodes have no step at the wire shaft or head. As a result, the stability is in part derived only from the encapsulating material in which the wire shaft is embedded. To ensure stability, the outer walls or the sleeves of the housing must be considerably longer than in the example embodiment of the present invention. Therefore, the resulting cavities to be filled with encapsulating material are also considerably larger than in the examples according to the present invention, and the entire wire head as well as a section of head wire 17 itself must thus also be surrounded by encapsulating material in order to obtain the desired stability.

As with conventional systems, the diode with a stepped wire connection or the wire itself is manufactured by extrusion in the approaches according to the present invention. Copper, for instance, is used as material for the head wire. The surface may be plated using nickel or a nickel alloy such as nickel phosphorus.

Whereas the conventional diodes shown in FIGS. 4, 5 and 6 require between 0.369 and 0.630 g plastic material as encapsulating material and for the sleeve, the two exemplary embodiments according to the present invention require 0.318 g of which 0.232 g are encapsulating material (FIG. 1), or 0.323 g of which 0.242 g are encapsulating material (FIG. 2), or 0.316 g in a further optimization of the embodiment according to FIG. 2.

1-7. (canceled)

8. A diode, comprising:
a press-fit base including an axially extending mounting region to mount a semiconductor chip;
a head wire provided with a head configured to be affixed to the semiconductor chip; and
a stabilization arrangement which include at least a sleeve and an encapsulating material filling cavities;
wherein the head wire includes a stepped wire connection having a region, which together with the sleeve and the press-fit base forms a housing, the cavities of the housing being filled with encapsulating material.

9. The diode as recited in claim 8, press-fit base, wherein the head wire is made of copper, a surface of the head wire having a nickel or a nickel alloy coating.

10. The diode as recited in claim 9, wherein the coating is made of nickel phosphorus.

11. The diode as recited in claim 8, wherein the encapsulating material is an epoxy.

12. The diode as recited in claim 8, wherein only the head of the head wire, which is inside the housing, is surrounded by the encapsulating material.

13. The diode as recited in claim 8, wherein the head includes at least two regions having different diameters.

14. The diode as recited in claim 8, wherein the head is cone-shaped or bell-shaped.

15. A method for manufacturing a diode, comprising:
providing a press-fit base, the press-fit base including an axially extending mounting region to mount a semiconductor chip;
providing a head wire with a head configured to be affixed to the semiconductor chip, the head wire including a stepped wire connection region;
forming a housing using the stepped wire connection region and a sleeve; and
filling cavities of the housing with an encapsulating material.
